(19) United States
(12) Patent Application Publication
(10) Pub. No.: US 2006/0094202 A1
(43) Pub. Date: May 4, 2006

(54) Semiconductor array and method for manufacturing a semiconductor array

(75) Inventor: Christoph Bromberger, Heilbronn (DE)

Correspondence Address: BIRCH STEWART KOLASCH & BIRCH, PO BOX 747, FALLS CHURCH, VA, 22040-0747, US

(73) Assignee: ATMEL GERMANY GMBH, Heilbronn (DE)

(21) Appl. No.: 11/265,270

(22) Filed: Nov. 3, 2005

(30) Foreign Application Priority Data
Nov. 3, 2004 (DE) 102004053016.5-33

(51) Int. Cl. H01L 21/76

(52) U.S. Cl. 438/424

(57) ABSTRACT

A process for manufacturing a semiconductor array, wherein a trench structure is introduced into a first monocrystalline semiconductor region, the trench structure is filled with an insulator, whereby a number of layers of the insulator together have a heat conductance greater than 20 W/mK, an amorphous silicon layer, which is crystallized out laterally over the insulator proceeding from the exposed surface, acting as the seed window, of the first semiconductor region, is deposited on the insulator and on an exposed surface of the first semiconductor region, so that a second, at least partially monocrystalline semiconductor region is formed on the insulator.

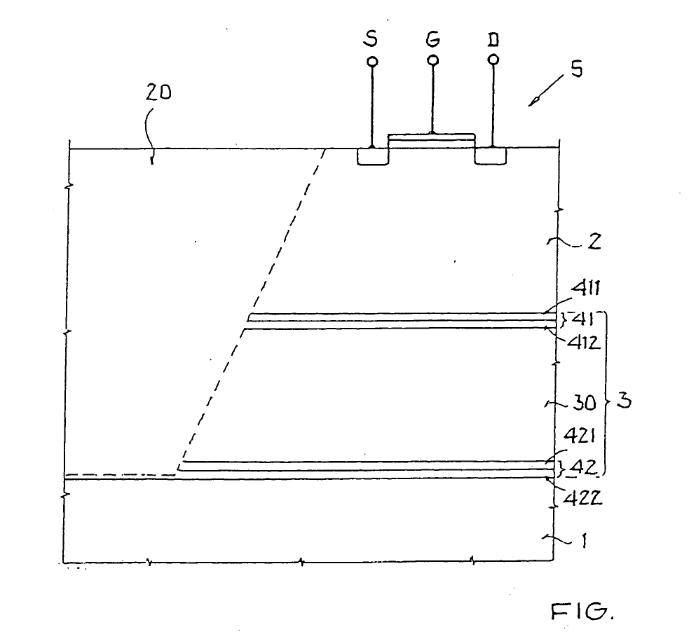

This nonprovisional application claims priority under 35 U.S.C. § 119(a) on German Patent Application No. DE 102004053016.5, which was filed in Germany on Nov. 3, 2004, and which is herein incorporated by reference.

### BACKGROUND OF THE INVENTION

1. Field of the Invention

The present invention relates to a semiconductor array and to a method for manufacturing a semiconductor array.

2. Description of the Background Art

Integrated microelectronic components are insulated by a dielectric layer of a (semi)conducting support wafer, in particular to reduce the tendency for crosstalk, for the purpose of greater insulation, and in more conductive substrates to reduce the substrate capacitance.

It is possible to use an SOI wafer material (Silicon-on-Insulator) for this purpose, in which a bottom handling wafer is separated by a continuous silicon dioxide layer from an overlying device wafer. This is disclosed, for example, in U.S. Pat. No. 6,552,395 B1, DD 250 403 A1, and U.S. Pat. No. 5,855,693.

Alternatively, laterally limited trenches in a handling wafer made of monocrystalline silicon may be filled with silicon dioxide. Outside the silicon-dioxide-filled trenches, monocrystalline silicon lines up with a surface. In a subsequent process step, a layer of amorphous silicon is applied, and this is caused to crystallize by suitable exposure to heat, proceeding from the exposed monocrystalline silicon regions as the seed layer (LEO: lateral epitaxial overgrowth).

Various manufacturing methods for semiconductor components by partial overgrowth of silicon dioxide layers with monocrystalline silicon by solid phase epitaxy are described in the Journal of the Electrochemical Society, 138 (1991), No. 12, pp. 3771-3777; Journal of Crystal Growth, 98 (1989), pp. 519-530; Applied Physics Letters, 49(7), 1986, pp. 397-399; Applied Physics Letters, 60(1), 1992, pp. 80-81; Applied Physics Letters, 52(20), 1988, pp. 1681-1683; Applied Physics Letters, 43(11), 1983, pp. 1028-1030; Applied Physics Letters, 52(21), 1988, pp. 1788-1790; Applied Physics Letters, 56(6), 1990, pp. 560-562; Applied Physics Letters, 48(12), 1986, pp. 773-775; Applied Physics Letters, 53(26), 1988, pp. 2626-2628; Applied Physics Letters, 49(20), 1986, pp. 1363-1365; Journal of Applied Physics, 64(6), 1988, pp. 3018-3023; Japanese Journal of Applied Physics, 35, 1996, pp. 1605-1610; and the Japanese Journal of Applied Physics, 31, 1992, pp. 1695-1701. Here, a silicon dioxide layer is first applied to a silicon wafer. Seed windows where the monocrystalline lattice of the wafer is exposed are opened in the silicon dioxide layer. An amorphous silicon layer is then applied and crystallized, proceeding from the seed openings.

These publications show that very thin layers with silicon dioxide as insulator were applied since the beginning of this technology in the early 1980s. For almost 30 years until the present, this method of overgrowth of silicon dioxide has been optimized, as is disclosed by the more recent data in U.S. Pat. No. 6,066,872.

### SUMMARY OF THE INVENTION

It is therefore an object of the present invention to provide a semiconductor array, which enables the highest possible integration density and power density of integrated power components on an insulator.

Hence, a semiconductor array with a first monocrystalline semiconductor region, an electric insulator, and a second, at least partially monocrystalline semiconductor region is provided. At least one active component, which forms a heat source during operation, is integrated into the second, at least partially monocrystalline semiconductor region.

Because the dielectric insulator is applied to the first monocrystalline semiconductor region, the at least one active, integrated component is electrically insulated from the first semiconductor region. Additional components, which must be insulated from the at least one active, integrated component of the second semiconductor region, are advantageously integrated in the first semiconductor region.

The second, at least partially monocrystalline semiconductor region is crystallized at least partially from an amorphous semiconductor material, proceeding from an exposed surface of the first monocrystalline semiconductor region as a seed window. For the insulation, the second monocrystalline semiconductor region partially covers the electric insulator.

The electric insulator can have at least one layer made of at least one of the materials of intrinsic silicon carbide (SiC), silicon nitride (Si₃N₄), aluminum nitride (AlN), or beryllium oxide (BeO). The insulator includes a number of layers, the number being greater than or equal to one. The insulator can have a total thermal conductance greater than 20 W/mK, which is formed by the number of the layers altogether.

This total thermal conductance of 20 W/mK is thereby clearly above the thermal conductance of silicon dioxide of 1.4 W/mK, so that components with a higher power density, than can be achieved in the conventional art, may be used particularly within high-frequency circuits, whereby their dissipated heat can be removed via the electric insulator into the employed substrate. This type of particularly line-type heat source can be, for example, a long, elongated bipolar transistor in the second monocrystalline semiconductor region.

For a largely dielectric insulation of the second monocrystalline semiconductor region from the first monocrystalline semiconductor region, the semiconductor material can be removed by etching and/or oxidation in the region of the seed window.

The insulator can have a stack of preferably several layers. In a first development variant, the dielectric insulator can have a layer of intrinsic silicon carbide (SiC). A second development variant, on the contrary, provides that the electric insulator can have a layer of silicon nitride (Si₃N₄).

Particularly for high-frequency applications, the electric insulator advantageously has a heat conductance greater than 100 W/mK. If, on the contrary, even an insulator with a heat conductance greater than or equal to 150 W/mK is used, it is possible to achieve a heat dissipation comparable to a silicon substrate.

Another embodiment of the invention provides that the second monocrystalline semiconductor region can have a silicon layer (Si) and/or a silicon-germanium layer (SiGe) with active regions of an integrated component.

It is also possible to use different materials individually or in combination as a dielectric in the insulator. Further, the electric insulator can have an aluminum nitride (AlN) layer.

According to another embodiment, the electric insulator can have a beryllium oxide (BeO) layer. Two embodiment variants enable the creation of a beryllium oxide layer.

The beryllium oxide (BeO) layer can be applied by electron-beam evaporation or sputtering of a beryllium oxide target. Alternatively, the layer of beryllium oxide (BeO) is created by oxidation of a beryllium layer (Be).

Also, a diffusion barrier layer can be placed between the first semiconductor region and the layer of beryllium oxide (BeO) and/or the layer of aluminum nitride (AlN). The diffusion barrier prevents diffusion of beryllium or aluminum into the first semiconductor region, which includes, for example, silicon.

A further diffusion barrier layer can be placed between the second semiconductor region and the layer of beryllium oxide (BeO) and/or the layer of aluminum nitride (AlN). This diffusion barrier layer prevents diffusion of beryllium or aluminum into the second semiconductor region, which, for example, has silicon or a monocrystalline mixed crystal.

The diffusion barrier layer can have a silicon dioxide layer, adjacent to the first semiconductor region and/or second semiconductor region, and a silicon nitride layer, adjacent to the layer of beryllium oxide (BeO) and/or the layer of aluminum nitride (AlN). In addition, the silicon nitride layer prevents the beryllium from reacting with the silicon dioxide at high temperatures to form a poorly soluble compound.

Another embodiment provides a layer of titanium nitride (TiN) as a diffusion barrier. It is also possible to combine a titanium nitride layer with other layers for a diffusion barrier.

To maintain a favorable geometry and particularly a substantially planar surface, one or several layers of the electric insulator can fill a trench structure patterned within the first monocrystalline semiconductor region.

A further aspect of the invention is an application of the previously described semiconductor array in an integrated high-performance circuit or in an integrated high-frequency circuit.

Another aspect of the invention is a method for manufacturing the semiconductor array, whereby an insulator is created with a heat conductance greater than 20 W/mK. Hence, a continuous insulator may also electrically insulate the active components from a handling wafer. In the method for manufacturing a semiconductor array, a trench structure can be introduced into a first monocrystalline semiconductor region and the trench structure is filled with an electric insulator. In this regard, several layers of the electric insulator together produce a thermal conductance greater than 20 W/mK.

Subsequently, an amorphous silicon layer, which is crystallized out laterally over the insulator proceeding from the exposed surface, acting as the seed window, of the first semiconductor region, is deposited on the electric insulator and on an exposed surface of the first semiconductor region, so that a second, at least partially monocrystalline semiconductor region is formed on the insulator.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawing which is given by way of illustration only, and thus, is not limitive of the present invention, and wherein the drawing illustrates a cross section through a semiconductor array according to an embodiment of the present invention.

### DETAILED DESCRIPTION

A schematic cross section through a semiconductor array is shown in the figure. In this exemplary embodiment, the first monocrystalline semiconductor region 1 is a single-crystal silicon with the orientation <100>. An insulator 3, which electrically insulates a second monocrystalline semiconductor region 2 from first monocrystalline semiconductor region 1, is applied to this first monocrystalline semiconductor region 1. The second monocrystalline semiconductor region 2 has one or more silicon layers and silicon-germanium layers, which are not shown in the figure. For example, a parasitic capacitance between component 5, shown schematically here as a field effect transistor, and first semiconductor region 1 is to be significantly reduced by the insulator.

Insulator 3 includes several layers 42 (422, 421), 30, and 41 (412, 411). The layer 30 is a dielectric that dominates the total heat conductance of insulator 3 because of the thickness of the layer 30. Dielectric layer 30 in this exemplary embodiment has beryllium oxide (BeO). Alternatively or in combination, dielectric 30 can have aluminum nitride (AlN).

Insulator 3 is adjacent with a first interface to the first semiconductor region 1 and with a second interface to the second semiconductor region 2. To prevent diffusion of beryllium (Be) into the first semiconductor region 1, a first diffusion barrier 42 is provided, which has a silicon dioxide layer 422, adjacent to the first semiconductor region 1, and a silicon nitride layer 421, adjacent to the dielectric 30. The silicon nitride layer as a result brings about the separation of the beryllium (Be) from silicon dioxide (SiO₂), because Be reacts with SiO₂ at high temperatures to form poorly soluble compounds.

An analogous structure applies to the second diffusion barrier 41, which is placed between the dielectric 30 and the second semiconductor region 2. The barrier has a silicon nitride layer 412, adjacent to dielectric 30, and a silicon dioxide layer 411, adjacent to second semiconductor region 2. Each diffusion barrier 41, 42 has a much smaller layer thickness compared with dielectric 30.

The second semiconductor region 2 is crystallized from one or more amorphously deposited materials proceeding from a seed window, not shown in the figure, in insulator 3. The region of the seed window has been removed by etching of a trench structure 20, so that the second semiconductor region 2 is distanced from the first semiconductor region 1 by the trench structure 20 and electrically insulated by insulator 3. Another component, not shown in the figure, may be formed within the trench structure.

Furthermore, active regions can be created within the first semiconductor region 1 by implantation or the trench structure 20 may be filled with a dielectric. These alternative or combinable additional process steps are also not shown in the figure.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A process for manufacturing a semiconductor array, the process steps comprising:
introducing a trench structure into a first monocrystalline semiconductor region;
filling the trench structure with an insulator, whereby a number of layers of the insulator together have a heat conductance greater than 20 W/mK; and
forming a second monocrystalline semiconductor region at least partially on the insulator by depositing an amorphous silicon layer, which is a seed window, and which is crystallized out laterally over the insulator proceeding from an exposed surface of the first monocrystalline semiconductor region, on the insulator and on the exposed surface of the first semiconductor region.

2. A semiconductor array comprising:
a first monocrystalline semiconductor region;
an insulator, which is applied to the first monocrystalline semiconductor region; and
a second, at least partially monocrystalline semiconductor region, which is crystallized at least partially from an amorphous semiconductor material that is a seed window, proceeding from an exposed surface of the first monocrystalline semiconductor region,
wherein the second, at least partially monocrystalline semiconductor region partially covers the insulator,
wherein the insulator has at least one layer of at least one of intrinsic silicon carbide (SiC), silicon nitride (Si₃N₄), aluminum nitride (AlN), or beryllium oxide (BeO), and
wherein the insulator has a total heat conductance greater than 20 W/mK.

3. The semiconductor array according to claim 2, wherein the insulator has a total heat conductance greater than 100 W/mK.

4. The semiconductor array according to claim 2, wherein the second monocrystalline semiconductor region has a silicon layer and/or a silicon-germanium layer (SiGe) with active regions of an integrated component.

5. The semiconductor array according to claim 2, wherein the layer of beryllium oxide (BeO) is applied by electron-beam evaporation or sputtering of a beryllium oxide target.

6. The semiconductor array according to claim 2, wherein the layer of beryllium oxide (BeO) is created by oxidation of a beryllium layer (Be).

7. The semiconductor array according to claim 2, wherein a diffusion barrier layer of the insulator is placed between the first semiconductor region and the layer of beryllium oxide (BeO) or the layer of aluminum nitride (AlN).

8. The semiconductor array according to claim 2, wherein a diffusion barrier layer of the insulator is placed between the second semiconductor region and the layer of beryllium oxide (BeO) or the layer of aluminum nitride (AlN).

9. The semiconductor array according to claim 7, wherein the diffusion barrier of the insulator has a silicon dioxide layer, which is adjacent to at least the first semiconductor region or the second semiconductor region, and wherein the diffusion barrier a silicon nitride layer, which is adjacent to the layer of beryllium oxide (BeO) or of aluminum nitride (AlN).

10. The semiconductor array according to claim 7, wherein the diffusion barrier layer of the insulator has a titanium nitride layer (TiN).

11. The semiconductor array according to claim 2, wherein one or more layers of the insulator fill a trench structure patterned within the first monocrystalline semiconductor region.

12. The semiconductor array according to claim 2, wherein the semiconductor array is a component in an integrated high-performance circuit.

13. The semiconductor array according to claim 2, wherein the semiconductor array is a component in an integrated high-frequency circuit.

14. A semiconductor array comprising:
a first semiconductor region;
a second semiconductor region; and
an insulator formed between the first semiconductor region and the second semiconductor region, the insulator including a dielectric layer, a first diffusion barrier, and a second diffusion barrier, the dielectric layer being formed between the first diffusion barrier and the second diffusion barrier.

15. The semiconductor array according to claim 14, wherein the first diffusion barrier and the second diffusion barrier are each formed by a silicon dioxide layer and a silicon nitride layer.

16. The semiconductor array according to claim 15, wherein the silicon dioxide layer of each of the first or second diffusion barriers is directly adjacent to a surface of the first or second semiconductor region.

17. The semiconductor array according to claim 14, wherein a thickness of the dielectric layer is greater than a thickness of the first or second diffusion barrier.

18. The semiconductor array according to claim 14, wherein the second semiconductor region is crystallized from an amorphous material deposited in a seed window.

19. The semiconductor array according to claim 18, wherein the seed window is formed in a portion of the insulator.

20. The semiconductor array according to claim 14, wherein the first or second diffusion layer substantially prevents diffusion of beryllium or aluminum.
